(19) United States
(12) Patent Application Publication
(10) Pub. No.: US 2025/0014889 A1
(43) Pub. Date: Jan. 9, 2025

(54) PROCESSING METHOD OF WAFER

(71) Applicant: DISCO CORPORATION, Tokyo (JP)

(72) Inventor: Akira MIZUTANI, Tokyo (JP)

(21) Appl. No.: 18/753,610

(22) Filed: Jun. 25, 2024

(30) Foreign Application Priority Data
Jul. 5, 2023 (JP) 2023-110819

(51) Int. Cl. H01L 21/02; B23K 26/53; B23K 101/40; H01L 21/18; H01L 21/324; H01L 21/67

(52) U.S. Cl. CPC H01L 21/02021; B23K 26/53; H01L 21/02013; H01L 21/187; H01L 21/324; H01L 21/67092; B23K 2101/40

(57) ABSTRACT

A wafer processing method includes a step of forming a bonded wafer by provisionally bonding a first wafer and a second wafer, a step of forming, with a laser beam, modified layers in an annular pattern and cracks, which spread from the modified layers, inside the first wafer, a step of increasing bonded strength of the bonded wafer by anneal processing, a step of removing an outer peripheral region on a side of the outer peripheral edge relative to the modified layers and the cracks, by positioning a cutting blade at the annular region of the first wafer, and causing the cutting blade to cut in from a side of the other side of the first wafer to a depth not reaching the second wafer, and a step of thinning the first wafer to a finish thickness by grinding the first wafer from the side of the other side.

### BACKGROUND OF THE INVENTION

### Field of the Invention

The present invention relates to a wafer processing method.

### Description of the Related Art

Keeping in step with the move toward low-profile and high-integration device chips in recent years, development of three-dimensionally stacked semiconductor wafers is under progress. For example, a through-silicon via (TSV) wafer enables electrodes of two chips to be connected by bonding both the chips to each other with TSVs.

Such a wafer is thinned by being ground in a state of being bonded to a support wafer, which is made from silicon, glass, ceramics, or the like, as a substrate. In general, a wafer is chamfered at an outer peripheral edge thereof. When the wafer is ground extremely thin, the outer peripheral edge is formed into what is generally called a knife edge, so that edge chipping is prone to occur during grinding. There is hence a possibility that the chipping may extend to devices and lead to damage to the devices.

As a countermeasure for a knife edge, what is generally called an edge trimming technique has been developed to cut an outer peripheral edge of a wafer in an annular profile on a side of a front surface of the wafer (see Japanese Patent No. 4895594). In addition, an edge trimming method has also been contrived. According to this edge trimming method, a first wafer, which has a device region with devices formed therein, and a second wafer are bonded together, and the first wafer is then irradiated with a laser beam along an outer peripheral edge of the device region to form a plurality of modified layers in an annular pattern inside the first wafer, thereby suppressing edge chipping, which occurs during grinding of the first wafer, from spreading to the devices (see Japanese Patent Laid-open No. 2020-057709).

### SUMMARY OF THE INVENTION

However, the method of Japanese Patent No. 4895594 has a possibility of causing chipping to occur to such an extent as to reach devices and damaging the devices during cutting, and also involves a problem that the devices are prone to contamination with contaminants due to production of a great deal of cutting debris. The method of Japanese Patent Laid-open No. 2020-057709 has a possibility of allowing the edge material of an outer peripheral surplus region, removal of which at the time of the grinding is desired, to remain without separation if the modified layers are formed on an inner side of a joined region between the first wafer and the second wafer. Further, even if the edge material of the outer peripheral surplus region can be separated at the time of the grinding, the separated edge material may be caught between a grinding wheel and the first wafer, and may hence damage the devices.

The present invention therefore has as an object thereof the provision of a wafer processing method, which can remove an outer peripheral surplus region, with damage to devices suppressed, in a grinding step of a bonded wafer.

In accordance with an aspect of the present invention, there is provided a wafer processing method including a bonded wafer forming step of forming a bonded wafer by bonding one side of a first wafer and one side of a second wafer, a modified layer forming step of, after the bonded wafer forming step is performed, forming modified layers in an annular pattern and cracks, which spread from the modified layers, inside the first wafer by irradiating an annular region on an inner side by a predetermined distance from an outer peripheral edge in the first wafer with a laser beam of a wavelength having transmissivity for the first wafer, an outer peripheral region removal step of, after the modified layer forming step is performed, removing an outer peripheral region of the first wafer, the outer peripheral region being on a side of the outer peripheral edge relative to the modified layers and the cracks, by positioning a cutting blade at the annular region of the first wafer, and causing the cutting blade to cut in from a side of the other side of the first wafer to a depth not reaching the second wafer, along the annular region, and a grinding step of, after the outer peripheral region removal step is performed, thinning the first wafer of the bonded wafer to a finish thickness by grinding the first wafer from the side of the other side.

In accordance with another aspect of the present invention, there is provided a wafer processing method including a bonded wafer forming step of forming a bonded wafer by provisionally bonding one side of a first wafer and one side of a second wafer, a modified layer forming step of, after the bonded wafer forming step is performed, forming modified layers in an annular pattern and cracks, which spread from the modified layers, inside the first wafer by irradiating an annular region on an inner side by a predetermined distance from an outer peripheral edge in the first wafer with a laser beam of a wavelength having transmissivity for the first wafer, an anneal processing step of, after the modified layer forming step is performed, increasing bonded strength between the first wafer and the second wafer by applying anneal processing to the bonded wafer, an outer peripheral region removal step of, after the modified layer forming step is performed, removing an outer peripheral region of the first wafer, the outer peripheral region being on a side of the outer peripheral edge relative to the modified layers and the cracks, by positioning a cutting blade at the annular region of the first wafer, and causing the cutting blade to cut in from a side of the other side of the first wafer to a depth not reaching the second wafer, along the annular region, and a grinding step of, after the anneal processing step and the outer peripheral region removal step are performed, thinning the first wafer of the bonded wafer to a finish thickness by grinding the first wafer from the side of the other side.

Preferably, in the outer peripheral region removal step, the first wafer may be cut along the annular region by the cutting blade being caused to cut in from the other side of the first wafer to a depth not reaching the modified layers.

Preferably, in the outer peripheral region removal step, a center in a thickness direction of the cutting blade may be positioned on a radially outer side of the annular region in the first wafer.

Preferably, in the outer peripheral region removal step, a center in a thickness direction of the cutting blade may be positioned on a radially inner side of the annular region in the first wafer.

The present invention can remove the outer peripheral surplus region, with damage to the devices suppressed, in the grinding step of the bonded wafer.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a perspective view depicting an example of a wafer to which a wafer processing method according to a first embodiment of the present invention is to be applied;

FIG. 2 is a fragmentary cross-sectional view taken along line II-II indicated in FIG. 1;

FIG. 3 is a flow chart illustrating a flow of the wafer processing method according to the first embodiment;

FIG. 4 is a perspective view depicting how a bonded wafer forming step illustrated in FIG. 3 is performed;

FIG. 5 is a partly cross-sectional side view depicting how a modified layer forming step illustrated in FIG. 3 is performed;

FIG. 6 is a fragmentary cross-sectional view depicting on an enlarged scale a portion of a bonded wafer obtained after the modified layer forming step illustrated in FIG. 3;

FIG. 7 is a partly cross-sectional side view depicting how an outer peripheral region removal step illustrated in FIG. 3 is performed;

FIG. 8 is a fragmentary cross-sectional view depicting an example of positioning of a cutting blade in FIG. 7;

FIG. 9 is a fragmentary cross-sectional view depicting another example of the positioning of the cutting blade in FIG. 7;

FIG. 10 is a fragmentary cross-sectional view depicting a further example of the positioning of the cutting blade in FIG. 7;

FIG. 11 is a partly cross-sectional side view depicting how a grinding step illustrated in FIG. 3 is performed;

FIG. 12 is a flow chart illustrating a flow of a wafer processing method according to a second embodiment of the present invention;

FIG. 13 is a partly cross-sectional side view depicting how a bonded wafer forming step illustrated in FIG. 12 is performed;

FIG. 14 is a fragmentary cross-sectional view schematically depicting details of bonding between joined surfaces in a bonded wafer after the bonded wafer forming step illustrated in FIG. 12;

FIG. 15 is a partly cross-sectional side view depicting an example of an anneal processing step illustrated in FIG. 12; and

FIG. 16 is a fragmentary cross-sectional view schematically depicting details of bonding between joined surfaces in a bonded wafer after the anneal processing step illustrated in FIG. 12.

### DETAILED DESCRIPTION OF THE PREFERRED EMBODIMENTS

With reference to the attached drawings, a description will hereinafter be made in detail of a first embodiment and a second embodiment of the present invention. However, the present invention shall not be limited by details that will be described in the following first and second embodiments. The elements of configurations that will hereinafter be described include those readily conceivable to persons skilled in the art and substantially the same ones. Further, the configurations that will hereinafter be described can be combined appropriately. Furthermore, various omissions, replacements, and modifications of configurations can be made without departing from the spirit of the present invention.

### First Embodiment

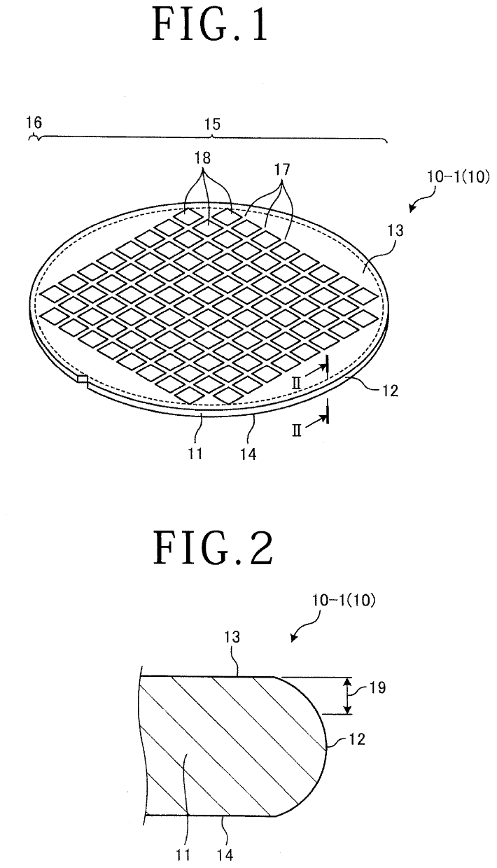

A processing method according to the first embodiment of the present invention for a wafer 10 will be described in reference to FIGS. 1 to 11. A description will first be made of the wafer 10 to be processed. FIG. 1 is a perspective view depicting an example of the wafer 10 to which the processing method according to the first embodiment is to be applied. FIG. 2 is a fragmentary cross-sectional view taken along line II-II indicated in FIG. 1.

The wafer 10 depicted in FIGS. 1 and 2 is a wafer, such as a disk-shaped semiconductor wafer or an optical device wafer, that uses silicon (Si), sapphire (Al₂O₃), gallium arsenide (GaAs), silicon carbide (SiC), or the like as a substrate 11, and is a silicon wafer in the first embodiment. As depicted in FIG. 2, the wafer 10 is chamfered at an outer peripheral edge 12 thereof such that the wafer 10 protrudes most toward an outer periphery at a center in a thickness direction thereof and has a round arc profile in cross-section from a front surface 13 to a back surface 14 of the substrate 11.

As depicted in FIG. 1, the wafer 10 has a device layer including, on the side of the front surface 13 of the substrate 11, a central region 15 and an outer peripheral region 16 surrounding the central region 15. The central region 15 has a plurality of scribe lines 17 set in a grid pattern on the front surface 13 of the substrate 11 and devices 18 formed in respective regions defined by the scribe lines 17. The outer peripheral region 16 surrounds the central region 15 over the entirety of a periphery thereof, and has no devices 18 formed therein.

In the first embodiment, the devices 18 constitute three dimensional (3D) Not AND (NAND) flash memories, and include electrode pads and through-silicon vias connected to the electrode pads. When the substrate 11 is thinned and the devices 18 are individually divided from the wafer 10, the through-silicon vias extend to the side of the back surface 14 of the substrate 11. The wafer 10 in the first embodiment is therefore what is generally called a TSV wafer in which the individually formed devices 18 each have through-silicon vias. It is however to be noted that the wafer 10 in this invention is not limited to such a TSV wafer having through-silicon vias as in the first embodiment, and may also be a device wafer having no through-silicon vias.

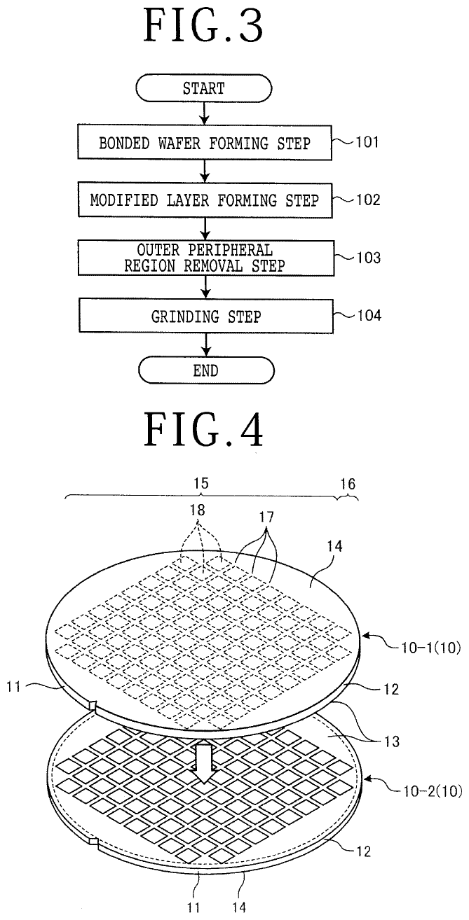

A description will next be made of a flow of the processing method according to the first embodiment for the wafer 10. FIG. 3 is a flow chart illustrating the flow of the processing method according to the first embodiment for the wafer 10. As illustrated in FIG. 3, the processing method of the first embodiment for the wafer 10 includes a bonded wafer forming step 101, a modified layer forming step 102, an outer peripheral region removal step 103, and a grinding step 104. The processing method of the first embodiment for the wafer 10 bonds a pair of wafers 10 each other on one sides thereof, and after formation of division starting points for removing the outer peripheral region 16, thins one of the wafers 10 (a first wafer 10-1) to a predetermined finish thickness 19 (see FIG. 2). It is to be noted that, in the first embodiment, the one sides are front surfaces 13.

It is to be noted that, when hereinafter distinguishing the individual wafers 10 from each other in the paired wafers 10, the one wafer 10 will be referred to as the “first wafer 10-1,” the other wafer 10 will be referred to as a “second wafer 10-2” (see FIG. 4), and that, when hereinafter not distinguishing the individual wafers 10, they will simply be referred to as the “wafer 10.” The other wafer, i.e., the second wafer 10-2, that will not be thinned will be described as a TSV wafer similar to the first wafer 10-1 in the first embodiment, but may also be a simple substrate wafer having no pattern in the present invention.

### (Bonded-Wafer Forming Step 101)

FIG. 4 is a perspective view depicting how the bonded wafer forming step 101 illustrated in FIG. 3 is performed. The bonded wafer forming step 101 forms the bonded wafer 20 by bonding the one side (in the first embodiment, the front surface 13) of the first wafer 10-1 and the one side (in the first embodiment, the front surface 13) of the second wafer 10-2.

In the bonded wafer forming step 101, the front surface 13 of the first wafer 10-1 and the front surface 13 of the second wafer 10-2 are first brought to face each other with an interval left therebetween as depicted in FIG. 4. The front surface 13 of the first wafer 10-1 and the front surface 13 of the second wafer 10-2 are then bonded together. As a consequence, the bonded wafer 20 is formed.

If a bonding layer is disposed between the first wafer 10-1 and the second wafer 10-2 on this occasion, the front surface 13 of the first wafer 10-1 and the front surface 13 of the second wafer 10-2 are bonded together via the bonding layer after the bonding layer is stacked on one of the front surface 13 of the first wafer 10-1 or the front surface 13 of the second wafer 10-2. It is to be noted that the bonding layer may be a double tack tape with self-adhesive material layers stacked on front and back surfaces, respectively, of a base material layer, may be an oxide layer, or may be one formed by an adhesive that contains resin or the like being applied.

As an alternative, the first wafer 10-1 and the second wafer 10-2 may be directly joined without use of any bonding layer. In the first embodiment, the first wafer 10-1 and the second wafer 10-2 are bonded together between the sides of the front surfaces 13 thereof. If the second wafer 10-2 is a substrate wafer, however, the first wafer 10-1 may be bonded at the front surface 13 thereof to either side of the second wafer 10-2.

### (Modified Layer Forming Step 102)

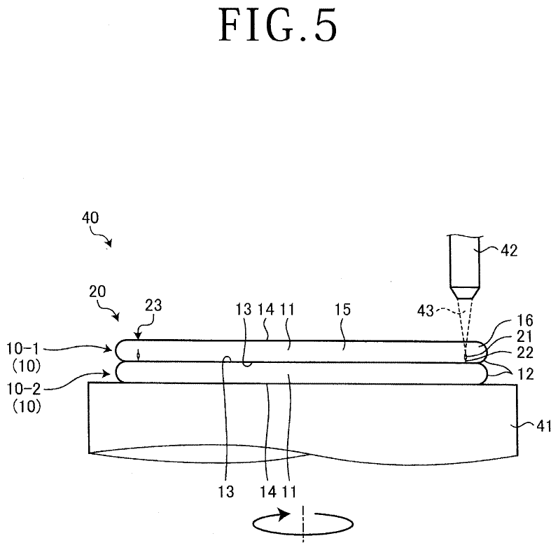

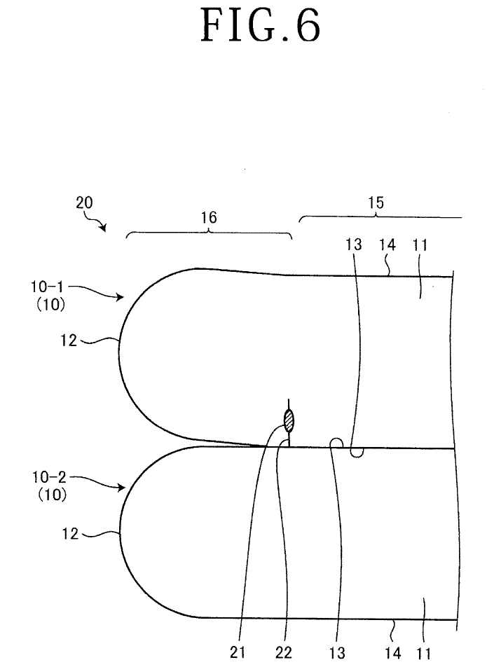

FIG. 5 is a partly cross-sectional side view depicting how the modified layer forming step 102 illustrated in FIG. 3 is performed. FIG. 6 is a fragmentary cross-sectional view depicting on an enlarged scale a portion of a bonded wafer 20 obtained after the modified layer forming step 102 illustrated in FIG. 3. The modified layer forming step 102 is performed after the bonded wafer forming step 101 is performed. The modified layer forming step 102 forms modified layers 21 in an annular pattern and cracks 22, which spread from the modified layers 21, inside the first wafer 10-1 by irradiating an annular region 23 on an inner side by a predetermined distance from the outer peripheral edge 12 in the first wafer 10-1 with a pulsed laser beam 43 of a wavelength having transmissivity for the first wafer 10-1.

In the modified layer forming step 102, the modified layers 21 and the cracks 22 are formed inside the first wafer 10-1 through stealth dicing by a laser processing apparatus 40 depicted in FIG. 5. The laser processing apparatus 40 includes a holding table 41 and a laser beam irradiation unit 42. The holding table 41 holds the wafers 10 on a holding surface thereof, and is rotatable about a vertical axis of rotation. The laser beam irradiation unit 42 irradiates, with the pulsed laser beam 43, the first wafer 10-1 held on the holding table 41, via the second wafer 10-2. The laser processing apparatus 40 further includes an undepicted moving unit that moves the holding table 41 and the laser beam irradiation unit 42 relative to each other, an undepicted imaging unit that images the first wafer 10-1 held on the holding table 41, via the second wafer 10-2, and the like.

In the modified layer forming step 102, the modified layers 21 are formed in the annular pattern inside the first wafer 10-1 by the pulsed laser beam 43 being applied from the side of the back surface 14 of the first wafer 10-1 and along a position on the inner side by the predetermined distance from the outer peripheral edge 12 in the first wafer 10-1. The expression “the position on the inner side by the predetermined distance from the outer peripheral edge 12” specifically means a boundary between the central region 15 and the outer peripheral region 16. The pulsed laser beam 43 is a pulsed laser beam of a wavelength having transmissivity for the first wafer 10-1, and is, for example, infrared rays (IR).

The term “modified layers 21” means regions in each of which one or more of the density, refractive index, mechanical strength, and other physical properties have changed to a level or levels different from the corresponding one or ones of surrounding regions. Each modified layer 21 is, for example, a fusion treated region, a cracked region, a dielectric breakdown region, a refractive index change region, a region where two or three of these regions exist mixed together, or the like. The modified layers 21 are lower in mechanical strength or the like than the other regions in the first wafer 10-1.

In the modified layer forming step 102, the second wafer 10-2 is first held, on the side of the back surface 14 thereof, by suction on the holding surface (upper surface) of the holding table 41. Alignment is then performed between the first wafer 10-1 and a condenser of the laser beam irradiation unit 42. Described specifically, the holding table 41 is moved by the undepicted moving unit to an irradiation region below the laser beam irradiation unit 42. The first wafer 10-1 is then imaged by the undepicted imaging unit, followed by alignment to make an irradiating portion of the laser beam irradiation unit 42 face in a vertical direction toward the position on the inner side by the predetermined distance from the outer peripheral edge 12 in the first wafer 10-1, and to then set a focal point 44 of the pulsed laser beam 43 inside the first wafer 10-1.

In the modified layer forming step 102, the pulsed laser beam 43 from the laser beam irradiation unit 42 is next applied from the side of the back surface 14 of the first wafer 10-1, with the holding table 41 kept rotating about the vertical axis of rotation. The pulsed laser beam 43 is therefore applied in the annular pattern along the position on the inner side by the predetermined distance from the outer peripheral edge 12 in the first wafer 10-1.

As a consequence, the modified layers 21 are formed in the annular pattern along the position on the inner side by the predetermined distance from the outer peripheral edge 12 in the first wafer 10-1, the cracks 22 are allowed to spread from the modified layers 21, and by interconnection between the modified layers 21 and the cracks 22, division starting points are formed in the annular pattern at the position on the inner side by the predetermined distance from the outer peripheral edge 12 in the first wafer 10-1. As depicted in FIG. 6, it is preferred to form, in the modified layer forming step 102, the modified layers 21 by the application of the pulsed laser beam 43 such that the cracks 22 spreading from the modified layers 21 appear on the side of the front surface 13 of the first wafer 10-1.

It is to be noted that, in the modified layer forming step 102, the first wafer 10-1 may be similarly irradiated a plurality of times with the pulsed laser beam 43 with the height position of the focal point 44 of the pulsed laser beam 43 changed every time in the thickness direction of the first wafer 10-1. As an alternative, the pulsed laser beam 43 may have a plurality of focal points 44 apart from one another in the thickness direction of the first wafer 10-1, and the first wafer 10-1 may be irradiated with the pulsed laser beam 43 such that a plurality of modified layers 21 are similarly formed in annular patterns overlapping in the thickness direction of the first wafer 10-1. If the pulsed laser beam 43 is applied the plurality of times from the side of the back surface 14 of the first wafer 10-1, modified layers 21 are similarly formed in annular patterns one after another from the side of the front surface 13 toward the side of the back surface 14. Preferably, the cracks 22 spread perpendicular to the front surface 13 of the first wafer 10-1. Here, the expression “perpendicular to the front surface 13 of the first wafer 10-1” more specifically indicates that an inclination of an approximate plane, which is formed by approximating the entire spreading cracks 22 to a plane, is in ±5 degrees, preferably in ±2 degrees. Moreover, it is possible to use a pulsed laser beam split into a plurality of beamlets in the traveling direction of the pulsed laser beam 43, a pulsed laser beam split into a plurality of beamlets in directions perpendicular to the traveling direction of the pulsed laser beam 43, or an oval-shaped pulsed laser beam having a major axis in the traveling direction of the pulsed laser beam 43 and a minor axis in a direction perpendicular to the traveling direction of the pulsed laser beam 43.

As depicted in FIG. 6, the first wafer 10-1, owing to the formation of the modified layers 21 and the cracks 22, produces a warp, which is protruding on the side of the front surface 13, at the outer peripheral region 16 on the side of the outer peripheral edge 12 relative to the modified layers 21 and the cracks 22.

Owing to this warp of the outer peripheral region 16, the bonded between the first wafer 10-1 and the second wafer 10-2 is released. It is to be noted that the release of the bonded owing to the warp is not limited to the interface between the device layer on the side of the front surface 13 of the first wafer 10-1 and the device layer on the side of the front surface 13 of the second wafer 10-2, and the bonded may also be released between the substrate 11 and the device layer in the first wafer 10-1 and between the substrate 11 and the device layer in the second wafer 10-2. When the modified layers 21 and the cracks 22 are formed in the annular pattern along the entire periphery of the first wafer 10-1, the modified layer forming step 102 is completed.

### (Outer Peripheral Region Removal Step 103)

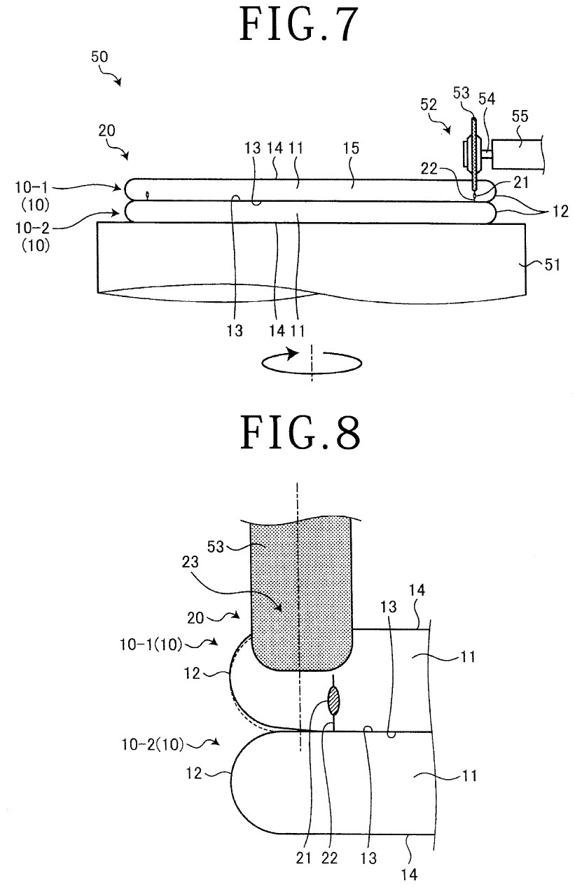

FIG. 7 is a partly cross-sectional side view depicting how the outer peripheral region removal step 103 illustrated in FIG. 3 is performed. The outer peripheral region removal step 103 is performed after the modified layer forming step 102 is performed. The outer peripheral region removal step 103 removes the outer peripheral region 16 on the side of the outer peripheral edge 12 relative to the modified layers 21 and the cracks 22 by positioning a cutting blade 53 at the annular region 23 of the first wafer 10-1, and causing the cutting blade 53 to cut in from the other side (in the first embodiment, the back surface 14) of the first wafer 10-1 to a depth not reaching the second wafer 10-2 and to cut the first wafer 10-1 along the annular region 23. In the first embodiment, the cutting blade 53 is caused to cut in to a depth not reaching the modified layers 21.

In the outer peripheral region removal step 103 in the first embodiment, the first wafer 10-1 is cut to a predetermined depth along the annular region 23 by a cutting apparatus 50 depicted in FIG. 7. The cutting apparatus 50 includes a holding table 51 and a cutting unit 52. The cutting unit 52 includes the cutting blade 53, a spindle 54, and a spindle housing 55. The cutting blade 53 has an annular cutting stone, and is fitted on the spindle 54 in such a manner that its axis of rotation coincides with that of the spindle 54. The spindle 54, as a rotating shaft member, rotates about an axis of rotation that is parallel to a holding surface of the holding table 51. The spindle housing 55 holds the spindle 54 rotatably about the axis of rotation thereof. The cutting apparatus 50 further includes an undepicted moving unit that moves the holding table 51 and the cutting blade 53 relative to each other, an undepicted imaging unit, and an undepicted cutting water supply unit that supplies cutting water to a processing point of the cutting blade 53.

In the outer peripheral region removal step 103, the second wafer 10-2 is first held, on the side of the back surface 14 thereof, by suction on the holding surface of the holding table 51. Alignment is then performed between the first wafer 10-1 and the cutting blade 53. Described specifically, the holding table 51 is moved by the undepicted moving unit to a processing region below the cutting blade 53. The first wafer 10-1 is then imaged by the undepicted imaging unit to perform alignment, so that the processing point of the cutting blade 53 is aligned with the annular region 23 of the first wafer 10-1.

In the outer peripheral region removal step 103, the supply of the cutting water toward the front surface 13 of the first wafer 10-1 is next initiated by the undepicted cutting water supply unit. Next, the cutting blade 53 is caused to cut in by the undepicted moving unit, and the holding table 51 is rotated about a vertical axis of rotation. The cutting blade 53 is then caused to cut in to a predetermined depth from the side of the front surface 13 of the first wafer 10-1.

This predetermined depth is at most a depth not reaching the second wafer 10-2. The predetermined depth is preferably a depth reaching the cracks 22 formed in the modified layer forming step 102. However, the predetermined depth is not necessarily required to reach the position of the cracks 22 at the time point that the cracks 22 have been formed in the modified layer forming step 102, because the cracks 22 spread further under a stress load by the cutting blade 53. If the thickness of the first wafer 10-1 is, for example, 775 μm and the formed position of the modified layers 21 closest to the back surface 14 is, for example, at a depth of 600 μm, the predetermined depth is 580 μm.

In the outer peripheral region removal step 103, upon cutting of the annular region 23 to the predetermined depth, a stress load is applied by the cutting blade 53, and the cracks 22 further spread toward the front surface 13 of the first wafer 10-1. As a consequence, the edge material of the outer peripheral region 16 is removed using, as division starting points, the modified layers 21, the cracks 22, and a groove cut by the cutting blade 53.

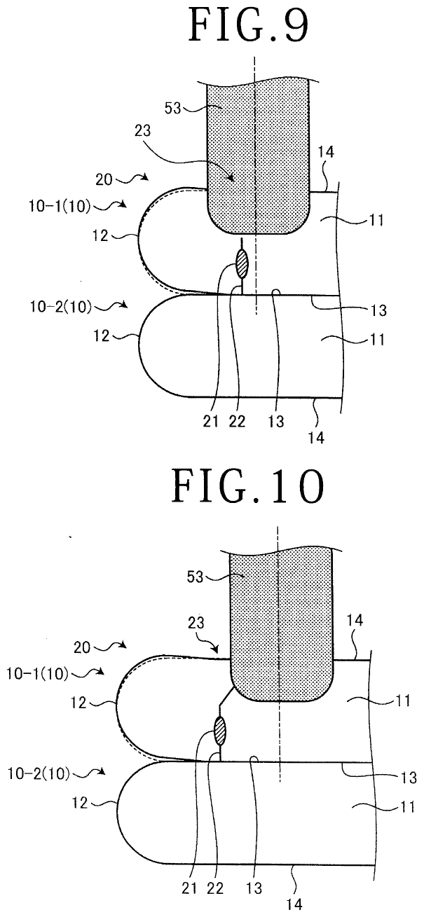

FIGS. 8 to 10 are fragmentary cross-sectional views depicting examples of positioning of the cutting blade 53 in FIG. 7. In the example depicted in FIG. 8, a center in a thickness direction of the cutting blade 53 is positioned on a radially outer side of the annular region 23 in the first wafer 10-1. In another example depicted in FIG. 9, the center in the thickness direction of the cutting blade 53 is positioned on a radially inner side of the annular region 23 in the first wafer 10-1. In a further example depicted in FIG. 10, the entirety in the thickness direction of the cutting blade 53 is positioned on the radially inner side of the annular region 23 in the first wafer 10-1.

If the center in the thickness direction of the cutting blade 53 is positioned on the radially outer side of the annular region 23 in the first wafer 10-1 as in FIG. 8, a load is directly applied to the outer peripheral region 16 itself, so that the removal of the outer peripheral region 16 is possible by merely bringing the cutting blade 53 into contact with the back surface 14 of the first wafer 10-1 without increasing the cut-in depth. Accordingly, the cut-in amount can be decreased, so that the production of cutting debris can be reduced. However, the outer peripheral region 16 may become prone to scatter in the cutting apparatus 50.

If the center in the thickness direction of the cutting blade 53 is positioned on the radially inner side of the annular region 23 in the first wafer 10-1 as in FIGS. 9 and 10, on the other hand, no load is directly applied to the outer peripheral region 16 itself, so that the scattering of the outer peripheral region 16 in the cutting apparatus 50 can be suppressed. It is therefore preferred to appropriately select, according to the size and material of the first wafer 10-1 to be processed, the size of the outer peripheral region 16, and the like, where the center in the thickness direction of the cutting blade 53 is positioned.

### (Grinding Step 104)

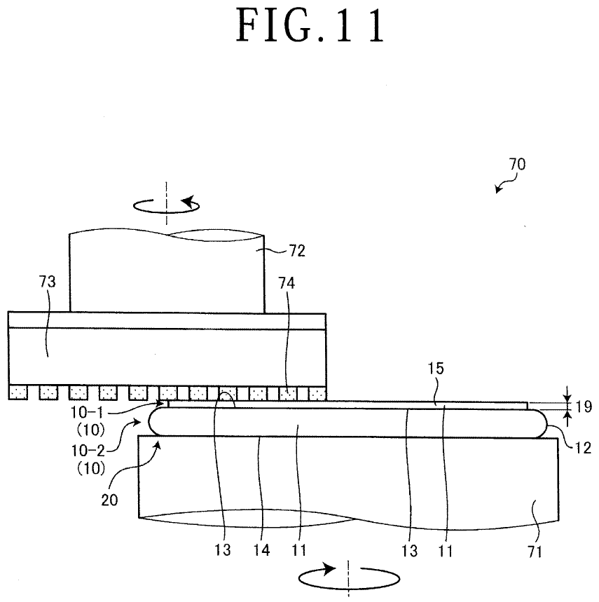

FIG. 11 is a partly cross-sectional side view depicting how the grinding step 104 illustrated in FIG. 3 is performed. The grinding step 104 is performed after the outer peripheral region removal step 103 is performed. The grinding step 104 grinds the first wafer 10-1 of the bonded wafer 20 from the other side (in the first embodiment, the back surface 14) of the first wafer 10-1 of the bonded wafer 20 to thin the first wafer 10-1 to the predetermined finish thickness 19.

In the grinding step 104 in the first embodiment, the first wafer 10-1 is thinned to the predetermined finish thickness 19 by being ground on the side of the back surface 14 with a grinding apparatus 70 illustrated in FIG. 11. The grinding apparatus 70 includes a holding table 71, a spindle 72 as a rotating shaft member, a grinding wheel 73 attached to a lower end of the spindle 72, grinding stones 74 secured to a lower surface of the grinding wheel 73, and an undepicted grinding fluid supply unit. The grinding wheel 73 rotates about an axis of rotation, which is parallel to an axis of rotation of the holding table 71.

In the grinding step 104, the second wafer 10-2 is first held, on the side of the back surface 14 thereof, by suction on a holding surface of the holding table 71. With the holding table 71 kept rotating about its axis of ration, the grinding wheel 73 is then rotated about its axis of rotation. A grinding fluid is supplied to a processing point by the undepicted grinding fluid supply unit, and at the same time, the grinding stones 74 of the grinding wheel 73 are brought closer at a predetermined feed rate toward the holding table 71, whereby the first wafer 10-1 is ground at the back surface 14 thereof by the grinding stones 74, and is thinned to the predetermined finish thickness 19.

### Second Embodiment

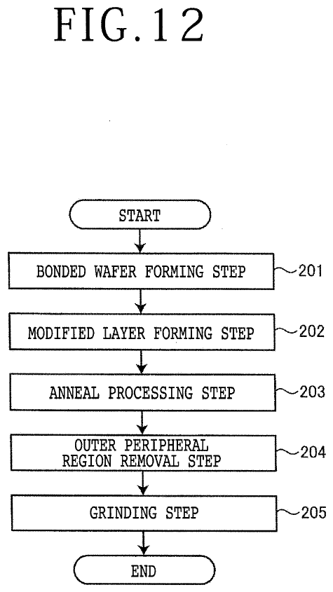

A processing method according to the second embodiment of the present invention for a wafer 10 will be described in reference to FIGS. 12 to 16. The wafer 10 to be processed in the second embodiment is similar to the wafer 10 processed in the first embodiment, and hence its description is omitted. In the description of the second embodiment, the same elements as those in the first embodiment are identified by the same reference numerals, and their description is omitted as appropriate.

A description will be made of a flow of the processing method of the second embodiment for the wafer 10. FIG. 12 is a flow chart illustrating the flow of the processing method according to the second embodiment for the wafer. As illustrated in FIG. 12, the processing method of the second embodiment for the wafer 10 includes a bonded wafer forming step 201, a modified layer forming step 202, an anneal processing step 203, an outer peripheral region removal step 204, and a grinding step 205.

It is to be noted that descriptions of the modified layer forming step 202, the outer peripheral region removal step 204, and the grinding step 205 in the second embodiment are omitted as the steps include procedures similar to those of the modified layer forming step 102, the outer peripheral region removal step 103, and the grinding step 104 in the first embodiment.

### (Bonded Wafer Forming Step 201)

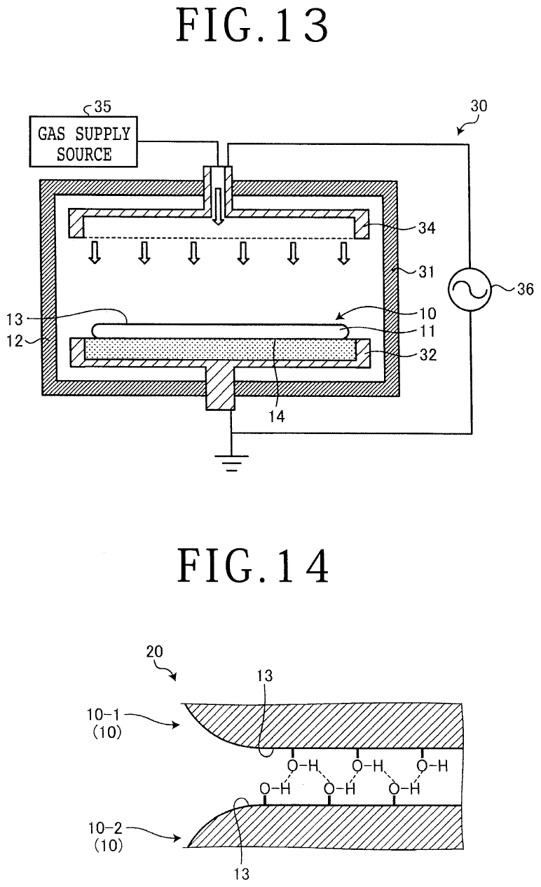

FIG. 13 is a partly cross-sectional side view depicting how the bonded wafer forming step 201 illustrated in FIG. 12 is performed. FIG. 14 is a fragmentary cross-sectional view schematically depicting details of bonding between joined surfaces in a bonded wafer 20 after the bonded wafer forming step 201 illustrated in FIG. 12. To join a first wafer 10-1 and a second wafer 10-2, the bonded wafer forming step 201 in the second embodiment provisionally joins one side (in the second embodiment, a front surface 13) of the first wafer 10-1 and one side (in the second embodiment, a front surface 13) of the second wafer 10-2, whereby the bonded wafer 20 is formed.

In the bonded wafer forming step 201 in the second embodiment, plasma processing is applied to at least one of the side of the first wafer 10-1 or the side of the second wafer 10-2, the sides being joined, so that with the at least one side activated, the first wafer 10-1 and the second wafer 10-2 are provisionally joined and bonded together. It is to be noted that the resulting provisional bonded is increased in bonded strength when anneal processing is applied in the anneal processing step 203 to be mentioned later.

In the bonded wafer forming step 201 in the second embodiment, the plasma processing is applied to the front surface 13 of each wafer 10 (each of the first wafer 10-1 and the second wafer 10-2) in a plasma processing apparatus 30 depicted in FIG. 13. The plasma processing apparatus 30 includes a chamber housing 31, a lower electrode 32, an upper electrode 34, a gas supply source 35, a radio frequency power supply 36, an undepicted electrostatic attraction system, an undepicted lift mechanism, an undepicted loading/unloading opening, and an undepicted exhaust system.

In the chamber housing 31, the lower electrode 32 and the upper electrode 34 are arranged vertically opposing each other. The lower electrode 32 is formed with an electrically conductive material, and has a disk-shaped holding portion to hold the wafer 10. Inside the holding portion, the undepicted electrostatic attraction system is formed. The wafer 10 placed on an upper surface of the holding portion can be fixed by electrostatic attraction by energizing the electrostatic attraction system.

The upper electrode 34 is formed with an electrically conductive material, and has a disk-shaped gas ejection portion that covers an upper side of the wafer 10 held on the holding portion of the lower electrode 32. The gas ejection portion is in communication with the gas supply source 35. The gas supply source 35 supplies a process gas such as argon (Ar), nitrogen (N₂), or oxygen (O₂) into the chamber housing 31 through the gas ejection portion. The upper electrode 34 is movable up and down relative to the lower electrode 32 by the undepicted lift mechanism.

The lower electrode 32 and the upper electrode 34 have an undepicted insulating member between themselves and a bottom wall and a top wall of the chamber housing 31, respectively, and are isolated from the chamber housing 31. The lower electrode 32 and the upper electrode 34 are connected to the radio frequency power supply 36. Based on control signals outputted from an undepicted controller, the radio frequency power supply 36 supplies predetermined radio frequency power to the lower electrode 32 and the upper electrode 34.

In the bonded wafer forming step 201, the wafer 10 is first loaded into the chamber housing 31 from the undepicted loading/unloading opening, and is placed on the holding portion of the lower electrode 32 such that the side of the front surface 13 is directed upward. The undepicted electrostatic attraction system is then activated, so that the wafer 10 is electrostatically attracted and held on the holding portion. Further, the undepicted loading/unloading opening is closed, so that a processing space in the chamber housing 31 is hermetically closed. Furthermore, the height position of the upper electrode 34 is adjusted by the undepicted lift mechanism such that the lower electrode 32 and the upper electrode 34 are brought into a predetermined positional relation suited for the plasma processing.

In the bonded wafer forming step 201, the undepicted exhaust system is next driven to bring the processing space in the chamber housing 31 to vacuum (low pressure). While the process gas is supplied at a predetermined flow rate from the gas supply source 35 to the processing space in the chamber housing 31, the predetermined radio frequency power is supplied from the radio frequency power supply 36 to the lower electrode 32 and the upper electrode 34, so that a plasma-state gas is supplied to the front surface 13 of the wafer 10. By performing such plasma processing, surface impurities such as organic matter adsorbed on the front surface 13 of the wafer 10 are removed, and a clean surface is exposed. Further, hydroxyl groups (OH groups) are bound to Si dangling bonds on the exposed, clean front surface 13. In other words, OH groups are formed on the front surface 13 of the wafer 10, the front surface 13 having been activated by the plasma processing.

In the bonded wafer forming step 201, the front surface 13 of the first wafer 10-1 and the front surface 13 of the second wafer 10-2 are next brought to face each other with an interval left therebetween as in the bonded wafer forming step 101 in the first embodiment depicted in FIG. 4. The front surface 13 of the first wafer 10-1 and the front surface 13 of the second wafer 10-2 are then bonded together. As a consequence, the bonded wafer 20 is formed.

On this occasion, the hydrogen atoms (H) of OH groups formed on the side of the front surface 13 of the first wafer 10-1 form hydrogen bonds with the oxygen atoms (O) of OH groups formed on the side of the front surface 13 of the second wafer 10-2. In parallel with the foregoing, the hydrogen atoms (H) of the OH groups formed on the side of the front surface 13 of the second wafer 10-2 also form hydrogen bonds with the oxygen atoms (O) of the OH groups formed on the side of the front surface 13 of the first wafer 10-1. As a consequence, the first wafer 10-1 and the second wafer 10-2 are attracted to each other through the hydrogen bonds, and are provisionally joined.

The plasma processing in the bonded wafer forming step 201 is performed on both the front surface 13 of the first wafer 10-1 and the front surface 13 of the second wafer 10-2, but may also be performed on only one of these surfaces. Further, in the bonded wafer forming step 201, the method of performing the plasma processing is not limited to the vacuum plasma method that generates plasma by reducing the pressure in the chamber housing 31 as described in the second embodiment, and may also be an open-type atmospheric pressure plasma method that scans the wafer 10 in its plane with a plasma generating electrode during a standby period with the wafer 10 placed on a stage.

### (Anneal Processing Step 203)

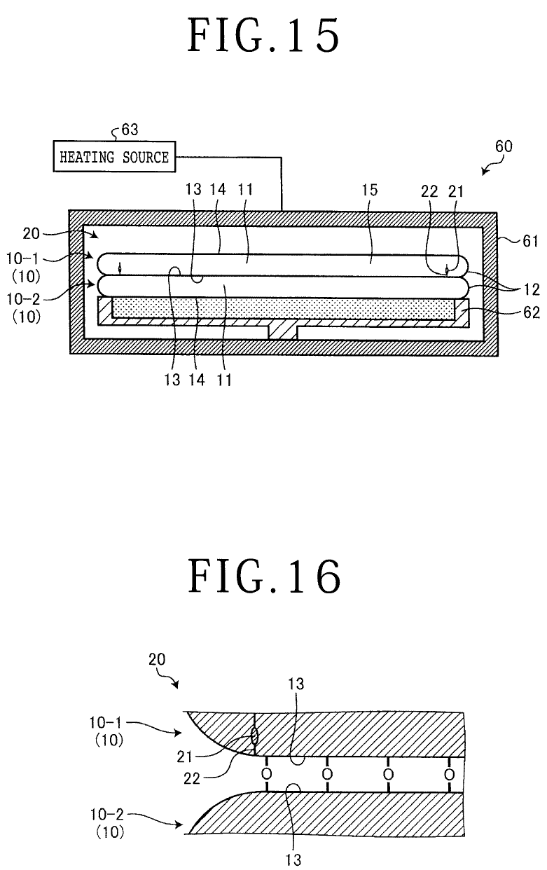

FIG. 15 is a partly cross-sectional side view depicting an example of the anneal processing step 203 illustrated in FIG. 12. FIG. 16 is a fragmentary cross-sectional view schematically depicting details of bonding between the joined surfaces in the bonded wafer 20 after the anneal processing step 203 illustrated in FIG. 12. The anneal processing step 203 is performed after the modified layer forming step 202 is performed but before the outer peripheral region removing step 204 is performed. The anneal processing step 203 increases bonded strength between the first wafer 10-1 and the second wafer 10-2 by applying anneal processing to the bonded wafer 20.

The anneal processing step 203 in the second embodiment is performed in an anneal processing apparatus 60 depicted in FIG. 15. The anneal processing apparatus 60 includes a chamber housing 61, a holding table 62, and a heating source 63. In the chamber housing 61, the holding table 62 is arranged. The holding table 62 can hold the bonded wafer 20 by suction on a holding surface. The chamber housing 61 is internally heated by the heating source 63. The heating source 63 includes, for example, infrared lamps. The holding table 62 may internally have another heating source to heat the bonded wafer 20 held on the holding surface of the holding table 62.

In the anneal processing step 203 in the second embodiment, the bonded wafer 20 is first loaded from an undepicted loading/unloading opening into the chamber housing 61, and is held on the holding table 62. The heating source 63 is then energized to heat the inside of the chamber housing 61. The wafer 10 in the second embodiment is a silicon wafer, and thus easily absorbs IR. When heated by the heating source 63 including the infrared lamps, the bonded wafer 20 is rapidly heated. It is to be noted that such a heating method is called “Rapid Thermal Anneal (RTA).”

On the joined surfaces of the first wafer 10-1 and the second wafer 10-2 of the bonded wafer 20 so heated, a dehydro-condensation reaction occurs. Described specifically, water (H₂O) molecules are lost from OH groups formed on the front surfaces 13, so that covalent bonds are formed via oxygen atoms (O) as depicted in FIG. 16. This leads to an improvement in bonded strength between the front surface 13 of the first wafer 10-1 and the front surface 13 of the second wafer 10-2.

It is to be note that, in the anneal processing step 203, the method of subjecting the bonded wafer 20 to the anneal processing is not limited to single wafer RTA that rapidly heats a plurality of bonded wafers 20 one after one in the chamber housing 61 described in the second embodiment, and may also be a batch-type anneal processing method that concurrently subjects a plurality of bonded wafers 20, which are arranged, for example, in a quartz furnace tube, to heat treatment by heating them with a heater from outside. In addition, the anneal processing method is not limited to a method that heats by IR, and may also be a method that heats on a hot plate.

As described above, the processing method of each embodiment for the wafer 10 subjects the first wafer 10-1 to cutting processing by the cutting blade 53 along the annular region 23 located on the inner side by the predetermined distance from the outer peripheral edge 12 of the bonded wafer 20 after forming the modified layers 21 and the cracks 22, which spread from the modified layers 21, by irradiation of the annular region 23 with the pulsed laser beam 43.

As a consequence, the edge material of the outer peripheral region 16 can be surely removed using the modified layers 21 as division starting points, thereby exhibiting an advantage of preventing the possibility of damage to devices 18 of the first wafer 10-1 by the edge material caught between the grinding wheel 73 and the first wafer 10-1 during the grinding. In addition, the production of cutting debris can be reduced compared with the case in which the first wafer 10-1 is processed as much as the thickness of the annular region 23 by merely cutting the first wafer 10-1 only.

It is to be noted that the present invention shall not be limited to the respective embodiments described above. In other words, the present invention can be practiced with various modifications within the scope not departing from the spirit of the present invention.

In the modified layer forming steps 102 or 202, for example, auxiliary modified layers may be additionally formed at predetermined positions in the peripheral direction of the outer peripheral region 16 between an inner peripheral boundary of the outer peripheral region 16 with the central region 15 and the outer peripheral edge 12 of the outer peripheral region 16. By these auxiliary modified layers, warp and separation in the outer peripheral region 16 are promoted. Moreover, the outer peripheral region 16 is divided into a plurality of smaller regions by the auxiliary modified layers, and thus the removal of the outer peripheral region 16 is further facilitated.

Further, in the second embodiment, the outer peripheral region removal step 204 may be performed before the anneal processing step 203 is performed. This enables the outer peripheral region 16 to be removed in a state that the bonded strength is weak.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A wafer processing method comprising:
a bonded wafer forming step of forming a bonded wafer by bonding one side of a first wafer and one side of a second wafer;
a modified layer forming step of, after the bonded wafer forming step is performed, forming modified layers in an annular pattern and cracks, which spread from the modified layers, inside the first wafer by irradiating an annular region on an inner side by a predetermined distance from an outer peripheral edge in the first wafer with a laser beam of a wavelength having transmissivity for the first wafer;
an outer peripheral region removal step of, after the modified layer forming step is performed, removing an outer peripheral region of the first wafer, the outer peripheral region being on a side of the outer peripheral edge relative to the modified layers and the cracks, by positioning a cutting blade at the annular region of the first wafer, and causing the cutting blade to cut in from a side of the other side of the first wafer to a depth not reaching the second wafer, along the annular region; and
a grinding step of, after the outer peripheral region removal step is performed, thinning the first wafer of the bonded wafer to a finish thickness by grinding the first wafer from the side of the other side.

2. The wafer processing method according to claim 1, wherein, in the outer peripheral region removal step, the first wafer is cut along the annular region by the cutting blade being caused to cut in from the other side of the first wafer to a depth not reaching the modified layers.

3. The wafer processing method according to claim 1, wherein, in the outer peripheral region removal step, a center in a thickness direction of the cutting blade is positioned on a radially outer side of the annular region in the first wafer.

4. The wafer processing method according to claim 1, wherein, in the outer peripheral region removal step, a center in a thickness direction of the cutting blade is positioned on a radially inner side of the annular region in the first wafer.

5. A wafer processing method comprising:
a bonded wafer forming step of forming a bonded wafer by provisionally bonding one side of a first wafer and one side of a second wafer;
a modified layer forming step of, after the bonded wafer forming step is performed, forming modified layers in an annular pattern and cracks, which spread from the modified layers, inside the first wafer by irradiating an annular region on an inner side by a predetermined distance from an outer peripheral edge in the first wafer with a laser beam of a wavelength having transmissivity for the first wafer;
an anneal processing step of, after the modified layer forming step is performed, increasing bonded strength between the first wafer and the second wafer by applying anneal processing to the bonded wafer;
an outer peripheral region removal step of, after the modified layer forming step is performed, removing an outer peripheral region of the first wafer, the outer peripheral region being on a side of the outer peripheral edge relative to the modified layers and the cracks, by positioning a cutting blade at the annular region of the first wafer, and causing the cutting blade to cut in from a side of the other side of the first wafer to a depth not reaching the second wafer, along the annular region; and
a grinding step of, after the anneal processing step and the outer peripheral region removal step are performed, thinning the first wafer of the bonded wafer to a finish thickness by grinding the first wafer from the side of the other side.

6. The wafer processing method according to claim 5, wherein, in the outer peripheral region removal step, the first wafer is cut along the annular region by the cutting blade being caused to cut in from the other side of the first wafer to a depth not reaching the modified layers.

7. The wafer processing method according to claim 5, wherein, in the outer peripheral region removal step, a center in a thickness direction of the cutting blade is positioned on a radially outer side of the annular region in the first wafer.

8. The wafer processing method according to claim 5, wherein, in the outer peripheral region removal step, a center in a thickness direction of the cutting blade is positioned on a radially inner side of the annular region in the first wafer.
